(19) United States
(12) Patent Application Publication
(10) Pub. No.: US 2012/0032172 A1
(43) Pub. Date: Feb. 9, 2012

(54) SEMICONDUCTOR DEVICE

(75) Inventors: Kosei NODA, Atsugi (JP); Yuta ENDO, Atsugi (JP); Toshinari SASAKI, Atsugi (JP)

(73) Assignee: SEMICONDUCTOR ENERGY LABORATORY CO., LTD., Kanagawa-ken (JP)

(21) Appl. No.: 13/193,755

(22) Filed: Jul. 29, 2011

(30) Foreign Application Priority Data
Aug. 6, 2010 (JP) 2010-177037

(51) Int. Cl. H01L 29/786

(52) U.S. Cl. 257/57; 257/E29.289

(57) ABSTRACT

A semiconductor device including the following components and a manufacturing method of the semiconductor device are provided. The semiconductor device includes a substrate; an oxide semiconductor layer over the substrate; a source electrode and a drain electrode whose end portion has a taper angle and whose upper end portion has a curved surface, the source electrode and the drain electrode being electrically connected to the oxide semiconductor layer; a gate insulating layer being in contact with a part of the oxide semiconductor layer and covering the oxide semiconductor layer, the source electrode, and the drain electrode; and a gate electrode overlapping with the oxide semiconductor layer and being over the gate insulating layer.

### BACKGROUND OF THE INVENTION

1. Field of the Invention

The present invention relates to a semiconductor device and a method for manufacturing the semiconductor device.

In this specification, a semiconductor device refers to a general device which can function by utilizing semiconductor characteristics, and an electro-optical device, a semiconductor circuit, and an electronic device are all semiconductor devices.

2. Description of the Related Art

A technique by which transistors are formed using semiconductor thin films over a substrate having an insulating surface has been attracting attention. Such transistors are applied to a wide range of electronic devices such as integrated circuits (ICs) or image display devices (display devices). A silicon-based semiconductor material is widely known as a material for a semiconductor thin film applicable to a transistor. As another material, an oxide semiconductor has been attracting attention.

For example, a transistor whose active layer includes an amorphous oxide containing indium (In), gallium (Ga), and zinc (Zn) and having an electron carrier concentration of less than 10¹⁸/cm³ is disclosed (see Patent Document 1).

A transistor including an oxide semiconductor is known to have a problem of low reliability because of high possibility of fluctuation in electric characteristics, although the transistor including an oxide semiconductor can operate at higher speed than a transistor including amorphous silicon and can be manufactured more easily than a transistor including polycrystalline silicon. For example, the threshold voltage of the transistor fluctuates after a bias-temperature test (BT test).

A bottom-gate bottom-contact transistor is disclosed in which deterioration in element characteristics which is caused by entry of impurities or increase in contact resistance between an oxide semiconductor layer and a source electrode layer and a drain electrode layer can be suppressed when a surface treatment such as plasma treatment is performed on a gate insulating layer, the source electrode layer, and the drain electrode layer and then the oxide semiconductor layer is formed (see Patent Document 2).

### REFERENCE

### Patent Document

[Patent Document 1] Japanese Published Patent Application No. 2006-165528
[Patent Document 2] Japanese Published Patent Application No. 2010-135771

### SUMMARY OF THE INVENTION

Variation and deterioration in electric characteristics of transistors including an oxide semiconductor considerably decrease the reliability of a semiconductor device. Therefore, an object of one embodiment of the present invention is to improve the reliability of the semiconductor device.

One embodiment of the present invention is a semiconductor device and a manufacturing method of the semiconductor device. The semiconductor device includes a substrate; an oxide semiconductor layer over the substrate; a source electrode and a drain electrode whose end portion has a taper angle and whose upper end portion has a curved surface, the source electrode and the drain electrode being electrically connected to the oxide semiconductor layer; a gate insulating layer being in contact with a part of the oxide semiconductor layer and covering the oxide semiconductor layer, the source electrode, and the drain electrode; and a gate electrode overlapping with the oxide semiconductor layer and being over the gate insulating layer.

The source electrode and the drain electrode are formed between the gate insulating layer and the oxide semiconductor layer.

Alternatively, the source electrode and the drain electrode are formed between the substrate and the oxide semiconductor layer.

A dry etching method is preferably used to form the source electrode and the drain electrode in which an end portion has a taper angle. The resist mask is reduced in size by the dry etching so that the source electrode and the drain electrode in which an end portion has a taper angle greater than or equal to 20° and less than 90° can be formed.

With use of the source electrode and the drain electrode in which the end portion has a taper angle, the coverage of a side surface of the oxide semiconductor layer or the gate insulating layer which is in contact with at least a side surface of the source electrode and the drain electrode can be improved. Therefore, breakdown due to electric field concentration caused by poor coverage of the source electrode and the drain electrode with a layer formed thereover hardly occurs.

The source electrode and the drain electrode in which the upper end portion has a curved surface can be formed in the following manner: plasma is generated in an atmosphere containing at least one of a rare gas (e.g., helium, neon, argon, krypton, or xenon), nitrogen, oxygen, and nitrogen oxide (e.g., nitrous oxide); and treatment is performed on the surfaces of the source electrode and the drain electrode using the plasma. Preferably, a rare gas that has low reactivity is used. Specifically, in a chamber containing the plasma, a bias may be applied to a substrate holder so that positive ions are accelerated with respect to the source electrode and the drain electrode. For example, a dry etching apparatus, a CVD apparatus, a sputtering apparatus, or the like may be used in the treatment.

Preferably, a reverse sputtering method using a sputtering apparatus is employed.

Thus, a curvature radius of an upper end portion of each of the source electrode and the drain electrode can be greater than or equal to 1/100 and less than or equal to ½ of a thickness of the source electrode and the drain electrode.

With use of the source electrode and the drain electrode whose upper end portion has a curved surface, electric field concentration on the oxide semiconductor layer or the gate insulating layer around the upper end portion can be relieved. The electric field concentration can be relieved; thus, leakage current from the portion of the electric field concentration is reduced, leading to improvement in reliability of the transistor.

Note that the transistor may include an insulating layer that is formed between the substrate and the oxide semiconductor layer and that is in contact with the oxide semiconductor layer. Alternatively, as an insulating layer that is formed between the substrate and the oxide semiconductor layer and that is in contact with the oxide semiconductor layer, an insulating layer from which oxygen is released by heating may be used. Alternatively, as the insulating layer, an insulating layer whose hydrogen concentration is less than or equal to 1.1×10²⁰ atoms/cm³ may be used.

To release oxygen by heating means that the released amount of oxygen which is converted into oxygen atoms is greater than or equal to 1.0×10¹⁸ atoms/cm³, preferably greater than or equal to 3.0×10²⁰ atoms/cm³ in thermal desorption spectroscopy (TDS).

In the above structure, the insulating layer from which oxygen is released by heating may include oxygen-excess silicon oxide (SiOₓ (X>2)). In the oxygen-excess silicon oxide (SiOₓ (X>2)), the number of oxygen atoms per unit volume is more than twice the number of silicon atoms per unit volume. The number of silicon atoms and the number of oxygen atoms per unit volume are measured by Rutherford backscattering spectrometry.

By supplying oxygen from the insulating layer to the oxide semiconductor layer, an interface state density between the insulating layer and the oxide semiconductor layer can be reduced. As a result, it is possible to sufficiently suppress trapping of charge or the like, which can be generated due to the operation of a semiconductor device, or the like, at an interface between the insulating layer and the oxide semiconductor layer.

Further, charge is caused due to oxygen deficiency in the oxide semiconductor layer in some cases. Generally, part of oxygen deficiency in an oxide semiconductor layer serves as a donor to generate an electron that is a carrier. As a result, the threshold voltage of a transistor shifts in the negative direction. This phenomenon occurs significantly on the back channel side. Note that the back channel in this specification refers to a region of the oxide semiconductor layer on the insulating layer side. Specifically, the back channel in this specification refers to a vicinity of a region where the oxide semiconductor layer is in contact with the insulating layer. Sufficient release of oxygen from the insulating layer to the oxide semiconductor layer can compensate oxygen deficiency in the oxide semiconductor layer which causes negative shift of the threshold voltage. The threshold voltage in this specification refers to a gate voltage which is needed to turn the transistor on. The gate voltage refers to a potential difference between a source electrode and a gate electrode when the potential of the source electrode is used as a reference potential.

In other words, when oxygen deficiency is generated in the oxide semiconductor layer, it becomes difficult to suppress trapping of charge at the interface between the insulating layer and the oxide semiconductor layer; however, by providing the insulating layer from which oxygen is released by heating as the insulating layer, an interface state density between the oxide semiconductor layer and the insulating layer and oxygen deficiency in the oxide semiconductor layer can be reduced and thus an adverse effect of trapping of charge at the interface between the oxide semiconductor layer and the insulating layer can be reduced.

Note that with use of a top-gate transistor, the back channel of the oxide semiconductor layer is prevented from being exposed to the atmosphere, moisture, a chemical solution, and plasma. The cleanliness of the back channel is maintained; therefore, a transistor with stable electric characteristics can be manufactured.

As described above, a semiconductor device with stable electric characteristics and high reliability can be manufactured using one embodiment of the present invention.

According to one embodiment of the present invention, a semiconductor device using an oxide semiconductor with stable electric characteristics and high reliability is provided.

### BRIEF DESCRIPTION OF THE DRAWINGS

In the accompanying drawings:

FIGS. 1A to 1C are a top view and cross-sectional views illustrating an example of a semiconductor device which is one embodiment of the present invention;

FIGS. 2A to 2E are cross-sectional views illustrating an example of a manufacturing process of a semiconductor device which is one embodiment of the present invention;

FIGS. 3A to 3C are a top view and cross-sectional views illustrating an example of a semiconductor device which is one embodiment of the present invention;

FIGS. 4A to 4E are cross-sectional views illustrating an example of a manufacturing process of a semiconductor device which is one embodiment of the present invention;

FIGS. 5A to 5E are views each illustrating an electronic device as a semiconductor device which is one embodiment of the present invention;

FIGS. 6A and 6B are images showing cross-sectional structures of transistors;

FIGS. 7A and 7B are graphs showing electric characteristics of transistors;

FIGS. 8A and 8B are graphs showing electric characteristics of transistors before and after a BT test;

FIGS. 9A and 9B are graphs showing electric characteristics of transistors before and after a BT test;

FIG. 10 is a graph showing a spectrum of a used light source; and

FIG. 11A and FIG. 11B are graphs showing electric characteristics of transistors in a dark state and a light state.

### DETAILED DESCRIPTION OF THE INVENTION

Hereinafter, embodiments of the present invention will be described in detail with reference to the accompanying drawings. However, the present invention is not limited to the description below and it is easily understood by those skilled in the art that the mode and details can be changed variously. Therefore, the present invention is not construed as being limited to description of the embodiments. In describing structures of the present invention with reference to the drawings, the same reference numerals are used in common for the same portions in different drawings. Note that the same hatch pattern is applied to similar parts, and the similar parts are not especially denoted by reference numerals in some cases.

Note that the ordinal numbers such as “first” and “second” in this specification are used for convenience and do not denote the order of steps or the stacking order of layers. In addition, the ordinal numbers in this specification do not denote particular names which specify the present invention.

### Embodiment 1

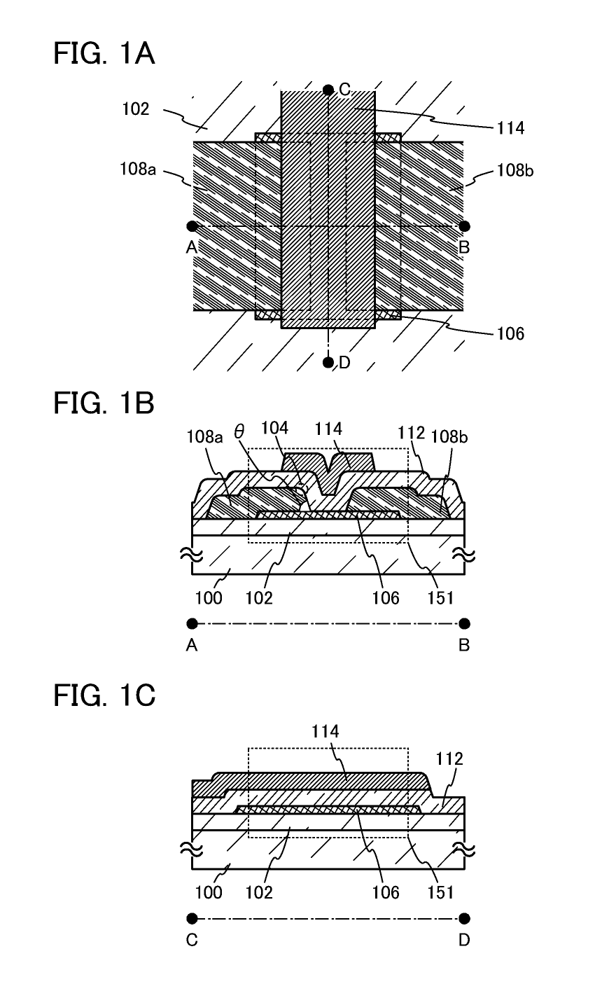

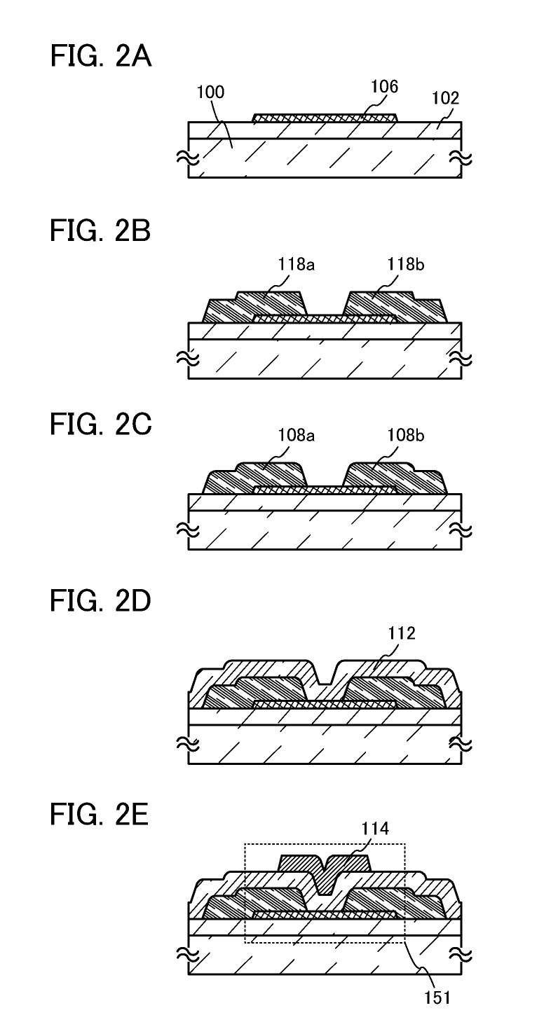

In this embodiment, one embodiment of a semiconductor device and one embodiment of a manufacturing method of the semiconductor device are described with reference to FIGS. 1A to 1C and FIGS. 2A to 2E.

FIGS. 1A to 1C are a top view and cross-sectional views of a transistor 151 that is a top-gate top-contact type transistor as an example of a semiconductor device of one embodiment of the present invention. Here, FIG. 1A is a top view, FIG. 1B is a cross-sectional view taken along alternate long and short dashed line A-B of FIG. 1A, and FIG. 1C is a cross-sectional view taken along alternate long and short dashed line C-D of FIG. 1A. Note that in FIG. 1A, some components of the transistor 151 (e.g., a gate insulating layer 112) are omitted for brevity.

The transistor 151 illustrated in FIGS. 1A to 1C includes a substrate 100, an insulating layer 102 over the substrate 100, an oxide semiconductor layer 106 over the insulating layer 102, a source electrode 108a and a drain electrode 108b over the oxide semiconductor layer 106, a gate insulating layer 112 covering the source electrode 108a and the drain electrode 108b and partly in contact with the oxide semiconductor layer 106, and a gate electrode 114 formed over the oxide semiconductor layer 106 with the gate insulating layer 112 provided therebetween. An end portion of the source electrode 108a and the drain electrode 108b has a taper angle θ and an upper end portion thereof has a curved surface 104.

The taper angle θ is greater than or equal to 20° and less than 90°. The preferable angle is greater than or equal to 40° and less than 85°. With such an angle, a break of the gate insulating layer 112 can be prevented and the coverage with the gate insulating layer 112 can be improved. For example, in the case where the taper angle θ is less than 20°, the area occupied by the tapered portion seen from the above is large in the source electrode 108a and the drain electrode 108b and thus, miniaturization of a transistor is difficult. In the case where the taper angle θ is greater than or equal to 90°, a step disconnection is made, which may cause leakage current or breakdown.

Note that when a layer having a taper angle (here, the source electrode 108a or the drain electrode 108b) is observed in a direction normal to a cross-sectional plane (a plane which is perpendicular to the surface of the substrate 100), “the taper angle θ” refers to an inclined angle of a tip portion inside the layer, which is formed by a side surface of the layer and a bottom surface thereof. For example, the taper angle θ corresponds to an angle of a lower end portion of the source electrode 108a or the drain electrode 108b which is in contact with the oxide semiconductor layer 106 when observed in the direction normal to the cross-sectional plane.

Further, a curvature radius of the curved surface 104 of the upper end portion of each of the source electrode 108a and the drain electrode 108b is greater than or equal to 1/100 and less than or equal to ½, preferably greater than or equal to 3/100 and less than or equal to ⅕ of a thickness of the source electrode 108a and the drain electrode 108b, whereby electric field concentration on the gate insulating layer 112 around the upper end portion can be relieved and leakage current from the upper end portion can be reduced. Therefore, a transistor with stable electric characteristics and high reliability can be manufactured.

As a material of the insulating layer 102, silicon oxide, silicon oxynitride, aluminum oxide, a mixed material of any of these, or the like may be used. Alternatively, the insulating layer 102 may be formed by stacking silicon oxide, silicon nitride, silicon oxynitride, silicon nitride oxide, aluminum oxide, aluminum nitride, a mixed material of any of these, or the like and the above material. For example, the insulating layer 102 has a stacked structure of a silicon nitride layer and a silicon oxide layer, thereby preventing impurity containing a hydrogen atom from entering the transistor 151 from the substrate or the like. In the case where the insulating layer 102 has a stacked structure, an oxide layer of silicon oxide, silicon oxynitride, aluminum oxide, a mixed material of any of these, or the like is preferably formed to be in contact with the oxide semiconductor layer 106. Note that the insulating layer 102 functions as a base layer of the transistor 151. As the insulating layer 102, an insulating layer from which oxygen is released by heating may be used.

Note that silicon oxynitride in this specification contains more oxygen than nitrogen in its composition and refers to a substance that preferably contains oxygen, nitrogen, silicon, and hydrogen at concentrations ranging from 50 at. % to 70 at. %, 0.5 at. % to 15 at. %, 25 at. % to 35 at. %, and 0 at. % to 10 at. %, respectively, in the case where measurements are conducted using Rutherford backscattering spectrometry (RBS) and hydrogen forward scattering spectrometry (HFS). Further, silicon nitride oxide contains more nitrogen than oxygen in its composition and refers to a substance that preferably contains oxygen, nitrogen, silicon, and hydrogen at concentrations ranging from 5 at. % to 30 at. %, 20 at. % to 55 at. %, 25 at. % to 35 at. %, and 10 at. % to 30 at. %, respectively, in the case where measurements are conducted using RBS and HFS. Note that percentages of nitrogen, oxygen, silicon, and hydrogen fall within the ranges given above, where the total number of atoms contained in the silicon oxynitride or the silicon nitride oxide is defined as 100 at. %.

For example, as the material of the insulating layer 102, silicon oxide (SiOₓ (X>2)) in which the number of oxygen atoms per unit volume is more than twice the number of silicon atoms per unit volume may be used.

At this time, the hydrogen concentration at an interface between the substrate 100 and the insulating layer 102 is preferably less than or equal to 1.1×10²⁰ atoms/cm³, because adverse influence due to diffusion of hydrogen from the interface between the substrate 100 and the insulating layer 102 to the oxide semiconductor layer 106 can be reduced. Therefore, negative shift of the threshold voltage of the transistor can be reduced and the reliability of the transistor can be increased.

As a material used for the oxide semiconductor layer 106, a four-component metal oxide such as an In—Sn—Ga—Zn—O-based material; a three-component metal oxide such as an In—Ga—Zn—O-based material, an In—Sn—Zn—O-based material, an In—Al—Zn—O-based material, a Sn—Ga—Zn—O-based material, an Al—Ga—Zn—O-based material, a Sn—Al—Zn—O-based material, or an In—Hf—Zn—O-based material; a two-component metal oxide such as an In—Zn—O-based material, a Sn—Zn—O-based material, an Al—Zn—O-based material, a Zn—Mg—O-based material, a Sn—Mg—O-based material, an In—Mg—O-based material, or an In—Ga—O-based material; an In—O-based material; a Sn—O-based material; a Zn—O-based material; or the like may be used. Further, silicon oxide or oxide containing lanthanoid may be added to any of the above materials. Here, for example, an In—Ga—Zn—O-based material means an oxide layer containing indium (In), gallium (Ga), and zinc (Zn), and there is no particular limitation on the composition ratio. Further, the In—Ga—Zn—O-based material may contain another element in addition to In, Ga, and Zn.

The oxide semiconductor layer 106 may be a thin film formed using a material represented by the chemical formula, InMO₃(ZnO)ₘ (m>0). Here, M represents one or more metal elements selected from Ga, Al, Mn, and Co. For example, M may be Ga, Ga and Al, Ga and Mn, Ga and Co, or the like.

The concentration of an alkali metal and an alkaline earth metal in the oxide semiconductor layer 106 is preferably 2×10¹⁶ atoms/cm³ or lower, or 1×10¹⁸ atoms/cm³ or lower. When an alkali metal or an alkaline earth metal combines with an oxide semiconductor, part of the combination generates carriers and cause negative shift of the threshold voltage.

Since the oxide semiconductor layer 106 is in contact with the insulating layer 102 from which oxygen is released by heating, the interface state density between the insulating layer 102 and the oxide semiconductor layer 106 and oxygen deficiency in the oxide semiconductor layer 106 can be reduced. By reduction in the interface state density, fluctuation in threshold voltage between before and after a BT test can be small. Further, by reduction in oxygen deficiency, the amount of the negative shift of the threshold voltage is reduced and thus normally-off characteristics can be obtained.

As a conductive layer used for the source electrode 108a and the drain electrode 108b, for example, a metal layer containing an element selected from Al, Cr, Cu, Ta, Ti, Mo, and W, or a metal nitride layer containing any of the above elements as its component (e.g., a titanium nitride layer, a molybdenum nitride layer, or a tungsten nitride layer) is used. A high-melting-point metal layer of Ti, Mo, W, or the like or a metal nitride layer of any of these elements (e.g., a titanium nitride layer, a molybdenum nitride layer, or a tungsten nitride layer) may be stacked on either a bottom side or a top side, or both of a metal layer of Al, Cu, or the like. Note that in this specification, there is no particular distinction between a source electrode and a drain electrode. The terms a “source electrode” and a “drain electrode” are used for convenience of explaining transistor operation.

Alternatively, the conductive layer used for the source electrode 108a and the drain electrode 108b may be formed using a conductive metal oxide. As the conductive metal oxide, indium oxide (In₂O₃), tin oxide (SnO₂), zinc oxide (ZnO), indium tin oxide (In₂O₃—SnO₂; abbreviated to ITO), indium zinc oxide (In₂O₃—ZnO), or any of these metal oxide materials in which silicon oxide is contained is used.

A conductive layer whose resistance is higher than the resistance of the source and drain electrodes 108a and 108b and lower than the resistance of the oxide semiconductor layer 106 may be provided between the source and drain electrodes 108a and 108b and the oxide semiconductor layer 106. A material that can reduce contact resistance between the source and drain electrodes 108a and 108b and the oxide semiconductor layer 106 is employed for the conductive layer. Alternatively, a material that hardly extracts oxygen from the oxide semiconductor layer 106 is used for the conductive layer. With the conductive layer, reduction in the resistance of the oxide semiconductor layer 106 due to extraction of oxygen from the oxide semiconductor layer 106 can be suppressed and increase in contact resistance due to generation of oxide of the source and drain electrodes 108a and 108b can be suppressed. Alternatively, in the case where a material that hardly extracts oxygen from the oxide semiconductor layer 106 is used for the source and drain electrodes 108a and 108b, the conductive layer can be omitted.

The gate insulating layer 112 may have a structure similar to that of the insulating layer 102, and is preferably an insulating layer from which oxygen is released by heating. Note that a material having a high dielectric constant, such as yttria-stabilized zirconia, hafnium oxide, or aluminum oxide, may be used for the gate insulating layer considering the function of the gate insulating layer of the transistor. Alternatively, a material having a high dielectric constant, such as yttria-stabilized zirconia, hafnium oxide, or aluminum oxide, may be stacked on silicon oxide, silicon oxynitride, or silicon nitride, considering the gate withstand voltage and the interface state with the oxide semiconductor.

The gate electrode 114 is formed using a metal material such as molybdenum, titanium, tantalum, tungsten, aluminum, copper, neodymium, or scandium; a nitride of any of these materials; or an alloy material containing any of these materials as a main component, for example. Note that the gate electrode 114 may have a single-layer structure or a stacked structure.

A protective insulating layer and a wiring may be further provided over the transistor 151. The protective insulating layer may have a structure similar to that of the insulating layer 102. In order to electrically connect the source electrode 108a or the drain electrode 108b and a wiring, an opening may be formed in the insulating layer 102, the gate insulating layer 112, and the like. A second gate electrode may further be provided below the oxide semiconductor layer 106. Note that it is not always necessary but preferable to process the oxide semiconductor layer 106 into an island shape.

A channel length L refers to a distance between the source electrode 108a and the drain electrode 108b in the A-B direction in FIG. 1A. A channel width W refers to a distance between the source electrode 108a and the drain electrode 108b in the C-D direction in FIG. 1A.

Although not illustrated, ends of the oxide semiconductor layer 106 may be inside ends of the gate electrode 114.

An example of a manufacturing process of the transistor 151 in FIGS. 1A to 1C is described below with reference to FIGS. 2A to 2E.

First, the substrate 100 is prepared. At this time, the substrate 100 is preferably subjected to first heat treatment. The temperature of the first heat treatment is temperature at which hydrogen adsorbed onto or contained in the substrate can be desorbed, and typically higher than or equal to 100° C. and lower than the strain point of the substrate. A period of time of the first heat treatment is longer than or equal to one minute and shorter than or equal to 72 hours. The first heat treatment can reduce molecules containing hydrogen adsorbed onto a surface of the substrate, or the like. The first heat treatment is performed in an atmosphere which does not contain hydrogen, preferably performed in a high vacuum of 1×10⁻⁴ Pa or lower.

There is no particular limitation on a material or the like of the substrate 100 as long as the material has heat resistance enough to withstand at least heat treatment to be performed later. For example, a glass substrate, a ceramic substrate, a quartz substrate, or a sapphire substrate may be used as the substrate 100. Alternatively, a single crystal semiconductor substrate or a polycrystalline semiconductor substrate made of silicon, silicon carbide, or the like, a compound semiconductor substrate made of silicon germanium or the like, an SOI substrate, or the like may be used as the substrate 100. Still alternatively, any of these substrates provided with a semiconductor element may be used as the substrate 100.

Alternatively, a flexible substrate may be used as the substrate 100. In the case where a transistor is provided over the flexible substrate, the transistor may be formed directly on the flexible substrate, or the transistor may be formed over a different substrate and then separated from the substrate to be transferred to the flexible substrate. In order to separate the transistor from the substrate to be transferred to the flexible substrate, a separation layer is preferably provided between the different substrate and the transistor.

Next, the insulating layer 102 is formed over the substrate 100.

The insulating layer 102 is formed by a plasma CVD method, a sputtering method, or the like, for example. For the formation of the insulating layer from which oxygen is released by heating, a sputtering method is preferably used. The total thickness of the insulating layer 102 is 50 nm or more, preferably 200 nm or more. When the insulating layer 102 is formed to be thick, the amount of oxygen released from the insulating layer 102 can be increased. Alternatively, when the insulating layer 102 is formed to be thick, adverse influence due to diffusion of hydrogen existing at an interface between the substrate 100 and the insulating layer 102 can be reduced. The reason why the adverse influence due to diffusion of hydrogen can be reduced is that the physical distance from the interface between the substrate 100 and the insulating layer 102 which is a diffusion source of hydrogen to the oxide semiconductor layer 106 is long.

In the case where a mixed gas of oxygen and a rare gas is used as a deposition gas when the insulating layer from which oxygen is released by heating is formed by a sputtering method, the ratio of oxygen to the rare gas is preferably high. For example, the concentration of oxygen in the whole gas is preferably set to be higher than or equal to 6% and lower than 100%. Note that it is preferable to use only an oxygen gas as the deposition gas.

For example, a silicon oxide layer is formed by an RF sputtering method under the following conditions: quartz (preferably synthetic quartz) is used as a target; the substrate temperature is higher than or equal to 30° C. and lower than or equal to 450° C. (preferably higher than or equal to 70° C. and lower than or equal to 200° C.); the distance between the substrate and the target (the T-S distance) is greater than or equal to 20 mm and less than or equal to 400 mm (preferably greater than or equal to 40 mm and less than or equal to 200 mm); the pressure is higher than or equal to 0.1 Pa and lower than or equal to 4 Pa (preferably higher than or equal to 0.2 Pa and lower than or equal to 1.2 Pa); the high-frequency power is higher than or equal to 0.5 kW and lower than or equal to 12 kW (preferably higher than or equal to 1 kW and lower than or equal to 5 kW); and the proportion of O₂/(O₂+Ar) in the deposition gas is higher than or equal to 1% and lower than or equal to 100% (preferably higher than or equal to 6% and lower than or equal to 100%). Note that a silicon target can be used as the target instead of the quartz (preferably synthetic quartz) target. As the deposition gas, oxygen or a mixed gas of oxygen and argon is used.

Next, an oxide semiconductor layer is formed over the insulating layer 102 and then is processed to form the oxide semiconductor layer 106 having an island shape (see FIG. 2A).

Note that in the case where the first heat treatment is performed, steps from the first heat treatment to the formation of the oxide semiconductor layer are preferably conducted without exposure to the atmosphere. Further preferably, the steps are conducted without breaking a vacuum. By performing the steps from the first heat treatment to the formation of the oxide semiconductor without exposure to the atmosphere, contamination onto the surface of the substrate and adsorption of molecules containing hydrogen onto the surface of the substrate can be suppressed, and diffusion of hydrogen into the oxide semiconductor layer by heat treatment that is performed later can be reduced.

Then, second heat treatment may be performed. The temperature of the second heat treatment is preferably temperature at which oxygen can be supplied to the oxide semiconductor layer from the insulating layer from which oxygen is released by heating, and typically higher than or equal to 150° C. and lower than the strain point of the substrate 100. By the second heat treatment, oxygen is released from the insulating layer 102; thus, the interface state density between the insulating layer 102 and the oxide semiconductor layer and oxygen deficiency in the oxide semiconductor layer can be reduced. Note that the second heat treatment may be performed at any timing as long as it is performed after the formation of the oxide semiconductor layer. Further, the second heat treatment may be conducted plural times. The second heat treatment is performed in an oxidation gas atmosphere or an inert gas atmosphere. A period of time of the second heat treatment is longer than or equal to one minute and shorter than or equal to 72 hours.

The oxygen deficiency in the oxide semiconductor layer is reduced by the second heat treatment. Moreover, adverse influence due to diffusion of hydrogen existing on the surface of the substrate can be reduced; therefore, the transistor is manufactured to have normally-off characteristics.

A heat treatment apparatus is not limited to an electric furnace and the heat treatment apparatus can be an apparatus that heats an object to be processed by thermal radiation or thermal conduction from a medium such as a heated gas. For example, a rapid thermal anneal (RTA) apparatus such as a gas rapid thermal anneal (GRTA) apparatus or a lamp rapid thermal anneal (LRTA) apparatus is used. An LRTA apparatus is an apparatus for heating an object to be processed by radiation of light (an electromagnetic wave) emitted from a lamp such as a halogen lamp, a metal halide lamp, a xenon arc lamp, a carbon arc lamp, a high pressure sodium lamp, or a high pressure mercury lamp. A GRTA apparatus is an apparatus for performing heat treatment using a high-temperature gas. As the gas, an inert gas that does not react with an object to be processed by heat treatment, for example, nitrogen or a rare gas such as argon is used.

Note that an inert gas atmosphere is an atmosphere that contains nitrogen or a rare gas as its main component and, preferably, does not contain water, hydrogen, and the like. For example, the purity of nitrogen or a rare gas such as helium, neon, or argon introduced into a heat treatment apparatus is set to 6N (99.9999%) or higher, preferably 7N (99.99999%) or higher (i.e., the impurity concentration is 1 ppm or lower, preferably 0.1 ppm or lower). The inert gas atmosphere is an atmosphere that contains an inert gas as its main component and contains a reactive gas at a concentration lower than 10 ppm. The reactive gas is a gas that reacts with a semiconductor, metal, or the like.

Note that the oxidizing gas is oxygen, ozone, nitrous oxide, or the like, and it is preferable that the oxidizing gas does not contain water, hydrogen, and the like. For example, the purity of oxygen, ozone, or nitrous oxide introduced into a heat treatment apparatus is set to 6N (99.9999%) or higher, preferably 7N (99.99999%) or higher (i.e., the impurity concentration is 1 ppm or lower, preferably 0.1 ppm or lower). An oxidation gas mixed with an inert gas may be used for the oxidation gas atmosphere and includes an oxidation gas at least at a concentration higher than or equal to 10 ppm.

The oxide semiconductor layer is formed by a sputtering method, a vacuum evaporation method, a pulse laser deposition method, a CVD method, or the like, for example. The thickness of the oxide semiconductor layer is preferably greater than or equal to 3 nm and less than or equal to 50 nm. If the oxide semiconductor layer is too thick (e.g., a thickness of 100 nm or more), there is a possibility that a short channel effect might have a large impact and the transistor with small size might be normally on.

In this embodiment, the oxide semiconductor layer is formed by a sputtering method using an In—Ga—Zn—O-based oxide target.

As the In—Ga—Zn—O-based oxide target, for example, an oxide target with a composition ratio of In₂O₃:Ga₂O₃:ZnO=1:1:1 [molar ratio] is used, for example. Note that it is not necessary that the material and the composition ratio of the target are limited to the above. For example, an oxide target with a composition ratio of In₂O₃:Ga₂O₃:ZnO=1:1:2 [molar ratio] can be used.

The relative density of the oxide target is higher than or equal to 90% and lower than or equal to 100%, preferably higher than or equal to 95% and lower than or equal 99.9%. This is because, with use of the oxide target with a high relative density, the oxide semiconductor layer can be formed to be dense.

For example, the oxide semiconductor layer is formed as follows. However, the present invention is not limited to the following method.

An example of the deposition conditions is as follows: the distance between the substrate and the target is 60 mm, the pressure is 0.4 Pa, the direct-current (DC) power is 0.5 kW, and the deposition atmosphere is a mixed atmosphere of argon and oxygen (the flow rate of the oxygen is 33%). Note that a pulse DC sputtering method is preferable because powder substances (also referred to as particles or dust) generated in the deposition can be reduced and distribution of the film thickness can be uniform.

Next, a conductive layer serving as a source electrode and a drain electrode is formed over the oxide semiconductor layer 106. The conductive layer is processed into a source electrode 118a and a drain electrode 118b (see FIG. 2B). Note that the channel length L of the transistor is determined by the distance between the edge of the source electrode 118a and the edge of the drain electrode 118b which are formed here.

The source electrode 118a and the drain electrode 118b are processed using a resist mask formed through a photolithography process by a dry etching method. Etching is performing with the resist mask while reducing the resist mask in size, so that the end portions of the source electrode 118a and the drain electrode 118b can have a taper angle. Ultraviolet light, KrF laser light, ArF laser light, or the like is preferably used for light exposure at the time of forming a resist mask used in the etching.

In the case where light exposure is performed so that the channel length L is less than 25 nm, the light exposure at the time of forming the resist mask is preferably performed using, for example, extreme ultraviolet light having an extremely short wavelength of several nanometers to several tens of nanometers. In the light exposure with extreme ultraviolet light, the resolution is high and the focal depth is large. Thus, the channel length L of the transistor formed later can be short, which leads to high speed operation of a circuit.

The etching may be performed with use of a resist mask formed using a multi-tone mask. A resist mask formed using a multi-tone mask has a plurality of thicknesses and can be further changed in shape by ashing; thus, such a resist mask can be used in a plurality of etching steps for different patterns. Therefore, a resist mask corresponding to at least two kinds of different patterns can be formed with use of one multi-tone mask. That is, the steps can be simplified.

Note that in processing of the source electrode 118a and the drain electrode 118b, part of the oxide semiconductor layer 106 is etched, so that the oxide semiconductor layer having a groove (a depressed portion) is formed in some cases.

Then, plasma treatment is performed on the source electrode 118a and the drain electrode 118b so that the source electrode 108a and the drain electrode 108b whose upper end portion has a curved surface are formed (see FIG. 2C).

The plasma is generated in an atmosphere containing at least one of a rare gas, nitrogen, oxygen, and nitrogen oxide. The surfaces of the source electrode 118a and the drain electrode 118b are subjected to treatment using the plasma so that the upper end portion can have a curved surface. Preferably, a rare gas that has low reactivity is used. For example, in a chamber containing the plasma, a bias may be applied to a substrate holder so that positive ions are accelerated with respect to the source electrode 118a and the drain electrode 118b. For example, a dry etching apparatus, a CVD apparatus, a sputtering apparatus, or the like may be used.

A reverse sputtering method may be performed with a sputtering apparatus, for example. The conditions of the reverse sputtering method may be set as follows: the RF electric power applied to the substrate side is greater than or equal to 50 W and less than or equal to 300 W; the sputtering pressure is greater than or equal to 0.2 Pa and less than or equal to 10 Pa; and a sputtering gas is a rare gas typified by an argon gas. A period of time of the treatment is greater than or equal to 0.5 minutes and less than or equal to 20 minutes.

When the period of time of the plasma treatment is too short, the upper end portion of the source electrode 118a and the drain electrode 118b cannot have a curved surface when seen from the cross section. Further, when the period of time of the treatment is too long, the oxide semiconductor layer 106, the source electrode 108a, and the drain electrode 108b are made thin.

Positive ions collide with the surfaces of the source electrode and the drain electrode, so that the sharp upper end portions are rounded and thus the curved surface can be formed. This can be easily understood in consideration of the sputtering rate which reaches the local minimum value when the positive ions perpendicularly enter the substrate and becomes larger as the angle of incidence is close to 0° or 180°. In other words, when the positive ions are discharged perpendicularly toward the substrate (needless to say, in the sputtering method, ions are not always discharged perpendicularly toward the substrate, and ions are discharged to have some degree of angle even when the electrode and the substrate are provided to face each other), the sputtering rate at the top surface of the source electrode and the drain electrode is the smallest and the sputtering rate at the side surface of the source electrode and the drain electrode is large. The frequency of positive ion collision is reduced as close to lower end portions of the source electrode and the drain electrode and thus it is difficult to perform sputtering on the lower end portions of the source electrode and the drain electrode. Therefore, the upper end portion of the source electrode and the drain electrode is most likely subjected to sputtering and thus has the curved surface without a corner. This phenomenon becomes more pronounced as ratios of the thickness to the width of the source electrode and the drain electrode are larger. Note that in addition to the formation of the curved surface, the taper angle θ can be small.

In such a manner, a curvature radius of an upper end portion of each of the source electrode and the drain electrode is greater than or equal to 1/100 and less than or equal to ½ of a thickness of the source electrode and the drain electrode. With such a structure, electric field concentration on the gate insulating layer 112 around the upper end portion of the source electrode and the drain electrode can be relieved and thus a transistor with high reliability can be manufactured.

At this time, the surfaces of the source electrode 118a, the drain electrode 118b, and the oxide semiconductor layer 106 are planarized by the plasma treatment. This is because a projection is preferentially etched by the plasma treatment. Through the planarization, an interface with the gate insulating layer 112 that is formed later is preferable, and the number of defects of the transistor due to unevenness can be reduced. Note that the average surface roughness Ra of the oxide semiconductor layer, the source electrode, and the drain electrode are preferably less than or equal to 0.5 nm. Note that an “average surface roughness Ra” is obtained by three-dimensionally expanding a centerline average roughness defined by JIS (Japanese Industrial Standards) B0601 so as to be applied to a plane. The average surface roughness Ra can be expressed as an “average value of absolute values of deviations from a reference plane to a designated plane, and is defined with the following Formula 1.

$$Ra = \frac{1}{{S}_{0}} {\int }_{y 2}^{y 1} {\int }_{x 2}^{x 1} \vert f ( x , y ) - {Z}_{0} \vert d x d y \qquad [ Formula 1 ]$$

Note that, in Formula 1, S₀ represents the area of a measurement surface (a rectangular region which is defined by four points represented by the coordinates (x₁,y₁), (x₁,y₂), (x₂,y₁), and (x₂,y₂)), and Z₀ represents average height of the measurement surface.

Next, the gate insulating layer 112 is formed to cover the source electrode 108a and the drain electrode 108b and be in contact with part of the oxide semiconductor layer 106 (see FIG. 2D).

The gate insulating layer 112 is formed by a sputtering method, a plasma CVD method, or the like. The total thickness of the gate insulating layer 112 is preferably greater than or equal to 1 nm and less than or equal to 300 nm, further preferably greater than or equal to 5 nm and less than or equal to 50 nm As the thickness of the gate insulating layer 112 is larger, a short channel effect becomes significant more and the threshold voltage tends to shift more in the negative side. In addition, when the thickness of the gate insulating layer 112 is less than or equal to 5 nm, leakage current due to a tunnel current is increased.

Then, the gate electrode 114 is formed (see FIG. 2E). The gate electrode 114 is formed in such a manner that a conductive layer to be the gate electrode 114 is formed by a sputtering method, an evaporation method, a coating method, or the like, and then the conductive layer is etched using a resist mask.

Through the above steps, the transistor 151 can be manufactured.

Note that a back channel of the oxide semiconductor layer is not exposed to the atmosphere, moisture, a chemical solution, and plasma and thus cleanliness of the back channel is maintained; therefore, a transistor with stable electric characteristics can be manufactured.

According to this embodiment, a transistor with stable electric characteristics and high reliability can be provided.

### Embodiment 2

In this embodiment, a top-gate bottom-contact transistor 152 is described as another example of a semiconductor device that is different from the transistor 151. In the formation of the transistor 152, plasma treatment on a source electrode and a drain electrode and formation of an oxide semiconductor layer can be performed without breaking a vacuum.

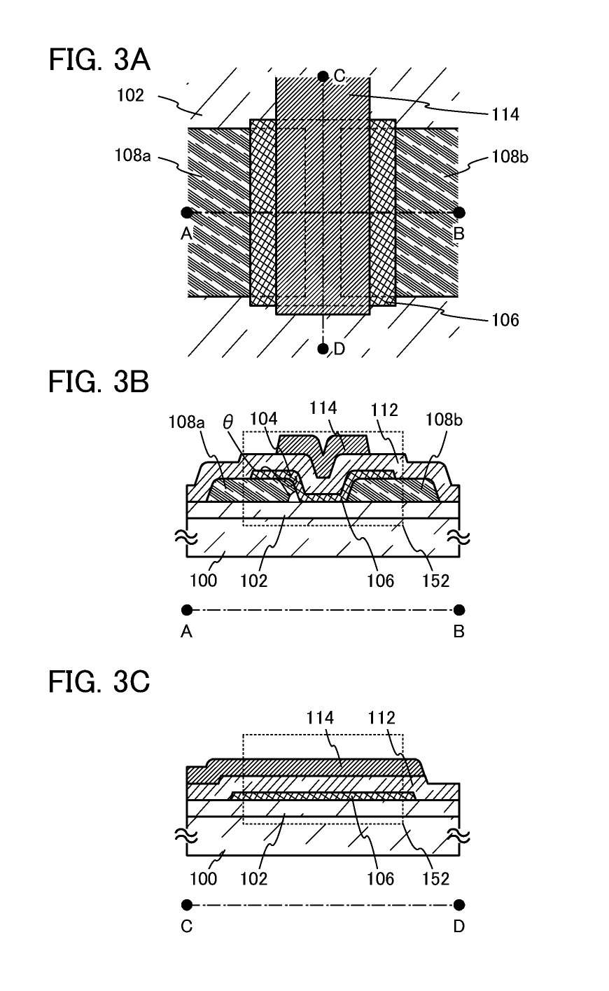

FIG. 3A is a top view of the transistor 152, FIG. 3B is a cross-sectional view taken along alternate long and short dashed line A-B of FIG. 3A, and FIG. 3C is a cross-sectional view taken along alternate long and short dashed line C-D of FIG. 3A. Note that in FIG. 3A, some components of the transistor 152 (e.g., the gate insulating layer 112) are omitted for brevity.

The transistor 152 illustrated in FIGS. 3A to 3C is the same as the transistor 151 in that the substrate 100, the insulating layer 102, the oxide semiconductor layer 106, the source electrode 108a, the drain electrode 108b, the gate insulating layer 112, and the gate electrode 114 are included and an end portion of the source electrode 108a and the drain electrode 108b has an angle θ and an upper end portion thereof has the curved surface 104. The differences between the transistor 152 and the transistor 151 are the positions where the oxide semiconductor layer 106 is connected to the source electrode 108a and the drain electrode 108b. In other words, in the transistor 152, a lower portion of the oxide semiconductor layer 106 is in contact with the source electrode 108a and the drain electrode 108b. The other components are similar to those of the transistor 151 in FIGS. 1A to 1C.

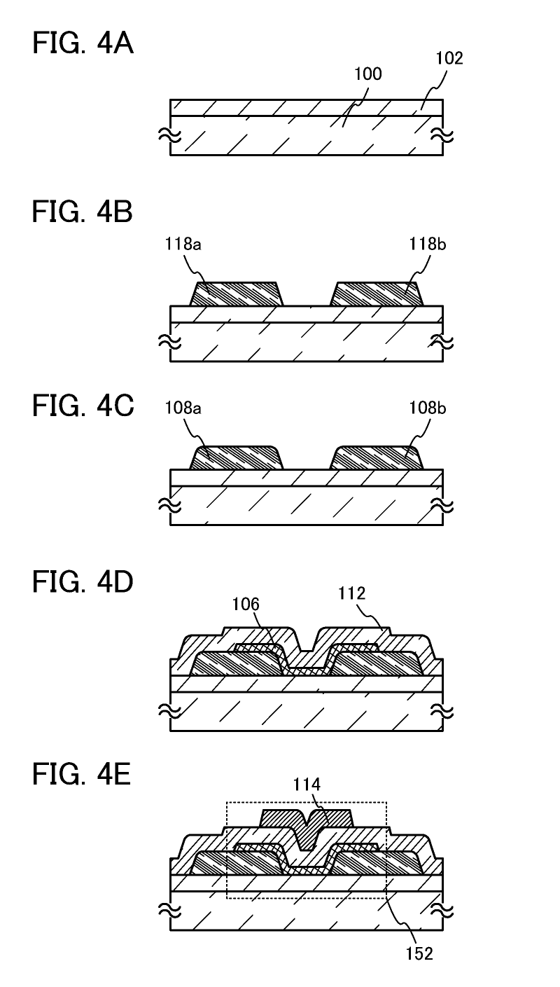

Next, an example of a manufacturing process of the transistor 152 in FIGS. 3A to 3C is described with reference to FIGS. 4A to 4E.

First, the substrate 100 is prepared. At this time, the substrate 100 is preferably subjected to the first heat treatment.

In the case of performing the first heat treatment, after the first heat treatment, the insulating layer 102 is preferably formed over the substrate 100 without exposure to the atmosphere. Further preferably, the first heat treatment and the formation of the insulating layer 102 is performed without breaking a vacuum (see FIG. 4A).

Next, a conductive layer for forming the source electrode and the drain electrode (including a wiring formed of the same layer as the source electrode and the drain electrode) is formed over the insulating layer 102, and the conductive layer is processed by a dry etching method to form the source electrode 118a and the drain electrode 118b (see FIG. 4B). At this time, the resist mask is reduced in size by the etching so that the end portions of the source electrode and the drain electrode can have a taper angle.

Then, plasma treatment is performed on the source electrode 118a and the drain electrode 118b so that the source electrode 108a and the drain electrode 108b whose end portion has a curved surface are formed (see FIG. 4C).

The plasma is generated in an atmosphere containing at least one of a rare gas such as helium, neon, argon, krypton, or xenon, nitrogen, oxygen, and nitrogen oxide such as nitrous oxide. The surfaces of the source electrode 118a and the drain electrode 118b are subjected to treatment using the plasma so that the upper end portion can have a curved surface.

When the period of time of the plasma treatment is too short, the upper end portion of the source electrode 108a and the drain electrode 108b cannot have a curved surface. Further, when the period of time of the treatment is too long, the insulating layer 102, the source electrode 108a, and the drain electrode 108b are made thin.

Specifically, a curvature radius of an upper end portion of each of the source electrode and the drain electrode is greater than or equal to 1/100 and less than or equal to ½ of a thickness of the source electrode and the drain electrode. With such a structure, electric field concentration on the oxide semiconductor layer 106 and the gate insulating layer 112 around the upper end portion of the source electrode and the drain electrode can be relieved and thus a transistor with high reliability can be manufactured.

Next, heat treatment similar to the first heat treatment is performed so as to reduce hydrogen adsorbed on the surfaces of the insulating layer 102, the source electrode 108a, and the drain electrode 108b. After that, an oxide semiconductor layer is formed without exposure to the atmosphere. Preferably, the heat treatment and the formation of the oxide semiconductor layer are performed without breaking a vacuum.

Alternatively, the steps from the plasma treatment on the source electrode 118a and the drain electrode 118b to the formation of the oxide semiconductor layer may be performed without breaking a vacuum. By performing the steps in such manner, after an oxide film, an organic contamination, or the like is removed from the surfaces of the source electrode 118a and the drain electrode 118b by the plasma treatment, an oxide film or an organic contamination can be prevented from being generated again. When there is no oxide film or organic contamination formed of the material of the source electrode 118a and the drain electrode 118b at the interface between the source electrode 108a and the drain electrode 108b and the oxide semiconductor layer, the contact resistance between the source electrode 108a and the drain electrode 108b and the oxide semiconductor layer can be reduced, so that decrease in an on-state current of the transistor can be suppressed. A deterioration in electric characteristics due to an oxide film or an organic contamination on the surfaces of the source electrode 108a and the drain electrode 108b, or a deterioration in electric characteristics due to light, gate bias, and temperature can be suppressed. Here, the deterioration in electric characteristics means a shift of the threshold voltage, decrease in an on-state current, or the like.

Next, second heat treatment may be performed.

Then, the oxide semiconductor layer is processed into the oxide semiconductor layer 106. After that, the gate insulating layer 112 is formed to cover the oxide semiconductor layer 106 and be in contact with part of the source electrode 108a and the drain electrode 108b (see FIG. 4D).

Then, the gate electrode 114 is formed (see FIG. 4E).

Through the above steps, the transistor 152 can be manufactured.

As described above, the transistor 152 can be manufactured without exposure of the back channel of the oxide semiconductor layer to the atmosphere, a chemical solution, and plasma.

According to this embodiment, a transistor with stable electric characteristics, less deterioration, and high reliability can be provided.

The structure, the method, and the like described in this embodiment may be combined with those described in the other embodiments as appropriate.

### Embodiment 3

A semiconductor device which is an embodiment of the present invention can be applied to a variety of memory devices and electronic devices (including game machines). Examples of electronic devices are a television set (also referred to as a television or a television receiver), a monitor of a computer or the like, a camera such as a digital camera or a digital video camera, a digital photo frame, a mobile phone handset (also referred to as a mobile phone or a mobile phone device), a portable game machine, a personal digital assistant, an audio reproducing device, and a large-sized game machine such as a pachinko machine. Examples of electronic devices each including the semiconductor device described in the above embodiment will be described.

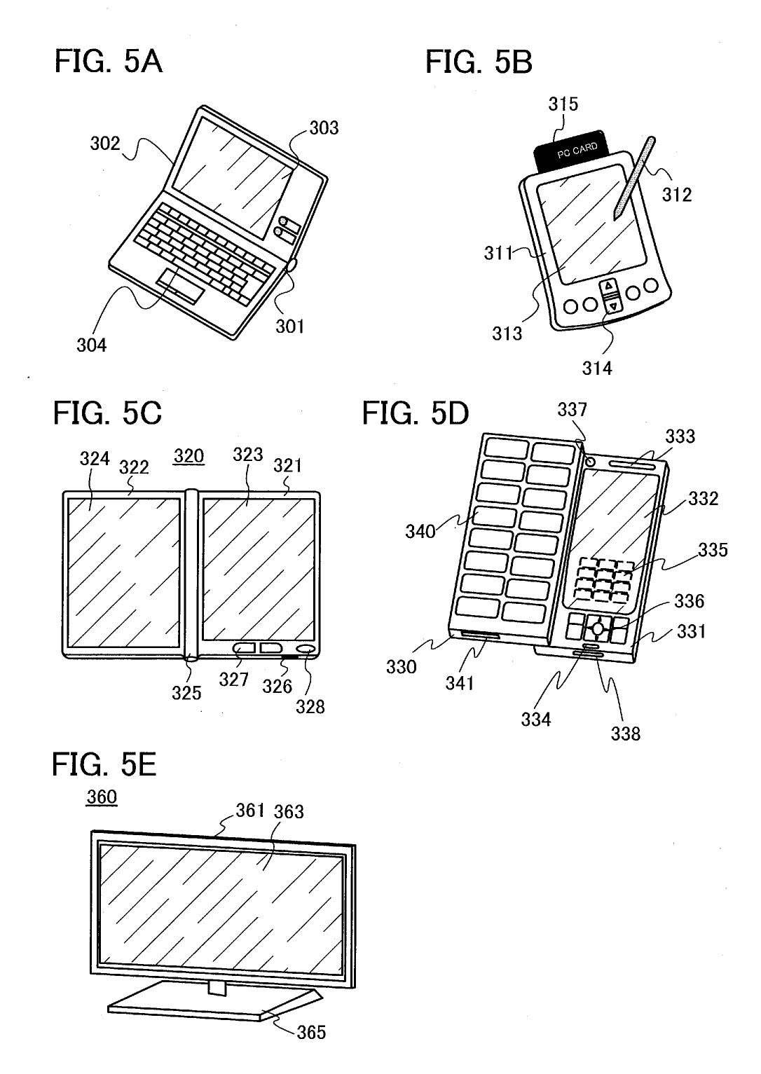

FIG. 5A illustrates a laptop personal computer, which includes a main body 301, a housing 302, a display portion 303, a keyboard 304, and the like. By applying the semiconductor device described in Embodiment 1 or 2, the laptop personal computer can have high reliability.

FIG. 5B illustrates a personal digital assistant (PDA), which includes a display portion 313, an external interface 315, an operation button 314, and the like in a main body 311. A stylus 312 is included as an accessory for operation. By applying the semiconductor device described in Embodiment 1 or 2, the personal digital assistant (PDA) can have higher reliability.

FIG. 5C illustrates an example of an e-book reader. For example, an e-book reader 320 includes two housings, a housing 321 and a housing 322. The housing 321 and the housing 322 are combined with a hinge 325 so that the e-book reader 320 can be opened and closed with the hinge 325 as an axis. With such a structure, the e-book reader 320 can be handled like a paper book.

A display portion 323 and a display portion 324 are incorporated in the housing 321 and the housing 322, respectively. The display portion 323 and the display portion 324 may display one image or different images. When the display portion 323 and the display portion 324 display different images, for example, text can be displayed on a display portion on the right side (the display portion 323 in FIG. 5C) and graphics can be displayed on a display portion on the left side (the display portion 324 in FIG. 5C). By applying the semiconductor device described in Embodiment 1 or 2, the e-book reader can have high reliability.

FIG. 5C illustrates an example in which the housing 321 is provided with an operation portion and the like. For example, the housing 321 is provided with a power switch 326, operation keys 327, a speaker 328, and the like. With the operation keys 327, pages can be turned. Note that a keyboard, a pointing device, or the like may also be provided on the surface of the housing on which the display portion is provided. Further, an external connection terminal (an earphone terminal, a USB terminal, or the like), a recording medium insertion portion, and the like may be provided on the back surface or the side surface of the housing. Moreover, the e-book reader 320 may have a function of an electronic dictionary.

The e-book reader 320 may have a configuration capable of wirelessly transmitting and receiving data. Through wireless communication, desired book data or the like can be purchased and downloaded from an e-book server.

FIG. 5D illustrates a personal digital assistant, which includes two housings, a housing 330 and a housing 331. The housing 331 includes a display panel 332, a speaker 333, a microphone 334, a pointing device 336, a camera lens 337, an external connection terminal 338, and the like. In addition, the housing 330 includes a solar cell 340 having a function of charge of the personal digital assistant, an external memory slot 341, and the like. Further, an antenna is incorporated in the housing 331. By applying the semiconductor device described in Embodiment 1 or 2, the personal digital assistant can have high reliability.

Further, the display panel 332 is provided with a touch panel. A plurality of operation keys 335 which are displayed as images is illustrated by dashed lines in FIG. 5D. Note that a boosting circuit by which a voltage output from the solar cell 340 is increased to be sufficiently high for each circuit is also included.

In the display panel 332, the display direction can be changed as appropriate depending on a usage pattern. Further, the personal digital assistant is provided with the camera lens 337 on the surface on which the display panel 332 is provided, and thus it can be used as a video phone. The speaker 333 and the microphone 334 can be used for videophone calls, recording and playing sound, and the like as well as voice calls. Moreover, the housings 330 and 331 in a state where they are opened as illustrated in FIG. 5D can be slid so that one overlaps the other; therefore, the size of the personal digital assistant can be reduced, which makes the personal digital assistant suitable for being carried.

The external connection terminal 338 can be connected to an AC adapter and various types of cables such as a USB cable, and charging and data communication with a personal computer are possible. Moreover, a larger amount of data can be saved and moved by inserting a recording medium to the external memory slot 341.

In addition to the above functions, an infrared communication function, a television reception function, or the like may be provided.

FIG. 5E illustrates an example of a television set. In a television set 360, a display portion 363 is incorporated in a housing 361. The display portion 363 can display images. Here, the housing 361 is supported by a stand 365. By applying the semiconductor device described in Embodiment 1 or 2, the television set 360 can have high reliability.

The television set 360 can be operated by an operation switch of the housing 361 or a separate remote controller. Further, the remote controller may be provided with a display portion for displaying data output from the remote controller.

Note that the television set 360 is provided with a receiver, a modem, and the like. With use of the receiver, general television broadcasting can be received. Furthermore, when the television set is connected to a communication network with or without wires via the modem, one-way (from a sender to a receiver) or two-way (between a sender and a receiver or between receivers) data communication can be performed.

The structures, the methods, and the like described in this embodiment may be combined as appropriate with any of the structures, the methods, and the like described in the other embodiments.

### Example 1

In this example, cross-sectional shapes of Sample 1 and Sample 2 which were manufactured were observed with a scanning transmission electron microscope (STEM).

A manufacturing method of Sample 1 and Sample 2 is described below. Note that the manufacturing process is employed for both Sample 1 and Sample 2 unless stated otherwise.

A difference between Sample 1 and Sample 2 is whether plasma treatment (reverse sputtering treatment) is performed on a second tungsten layer 506 and a silicon oxynitride layer 504 or not. In Sample 1, the reverse sputtering treatment was not performed on the second tungsten layer 506 and the silicon oxynitride layer 504, and in Sample 2, the reverse sputtering treatment was performed on the second tungsten layer 506 and the silicon oxynitride layer 504.

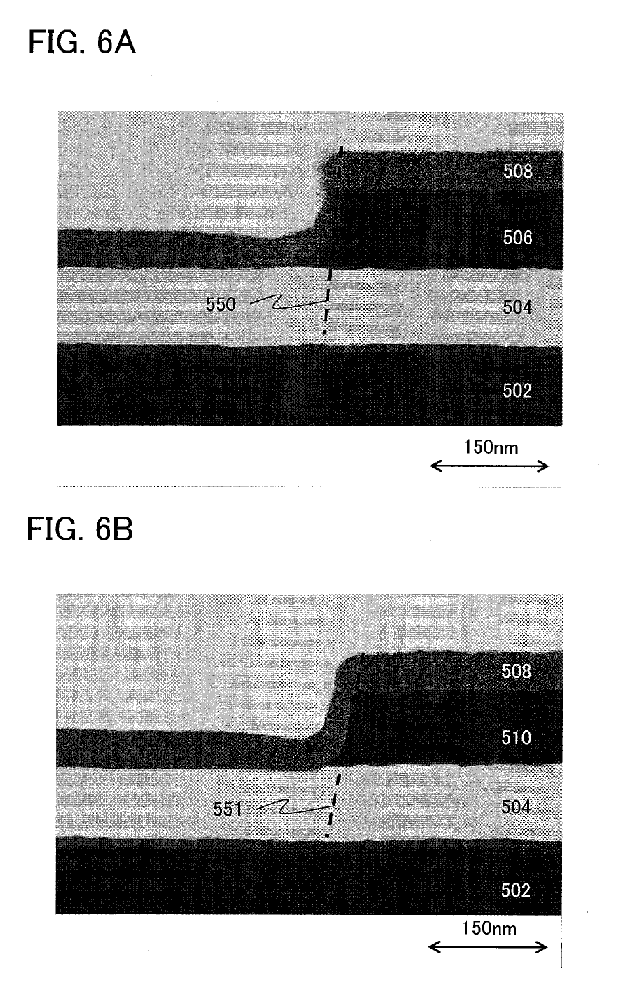

FIGS. 6A and 6B show cross-sectional shapes of Samples with a STEM. FIG. 6A shows Sample 1 and FIG. 6B shows Sample 2. The manufacturing method of Sample 1 and Sample 2 is described below.

First, a first tungsten layer 502 was formed over a substrate to have a thickness of 150 nm.

Next, the silicon oxynitride layer 504 was formed to have a thickness of 100 nm.

Then, a tungsten layer was formed to have a thickness of 100 nm, a resist mask was formed through a photolithography process, the tungsten layer was processed by a dry etching method, and then the resist mask was removed, so that the second tungsten layer 506 was formed.

Next, reverse sputtering was performed only on Sample 2 so that a second tungsten layer 510 whose upper end portion has a curved surface was formed. The conditions of the reverse sputtering were as follows.

Gas: Ar (50 sccm)

Electric power: 0.2 kW (13.56 MHz)

Pressure: 0.6 Pa

Temperature: room temperature

Time: 5 minutes

Next, an oxide semiconductor layer 508 was formed to have a thickness of 50 nm. The deposition conditions of the oxide semiconductor layer 508 were as follows.

Target: In—Ga—Zn—O (In₂O₃:Ga₂O₃:ZnO=1:1:2 [molar ratio]) target

Deposition gas: Ar (30 sccm), O₂ (15 sccm)

Electric power: 0.5 kW (DC)

Pressure: 0.4 Pa

T-S distance: 60 mm

Substrate temperature in deposition: 200° C.

Through the above steps, Sample 1 and Sample 2 were manufactured.

The upper end portion of the second tungsten layer in Sample 2 was curved in as compared with that in Sample 1 and the curvature radius of the second tungsten layer in Sample 2 was 10 nm

Note that the taper angle θ of Sample 1 was 85° and the taper angle θ of Sample 2 was 79°. The taper angle θ was calculated as follows. A tangent line (a tangent line 550, a tangent line 551) to the linear portion in the side surface of the second tungsten layer is drawn, the tangent line is regarded as a hypotenuse, and the thickness of the second tungsten layer is regarded as a side, whereby a right triangle is formed in the second tungsten layer. Then, from the base and height of the right triangle, the taper angle is calculated.

In Sample 1, the thickness of the oxide semiconductor layer 508 formed over the second tungsten layer 506 was smaller near the upper end portion of the second tungsten layer 506; therefore, the oxide semiconductor layer 508 was nonuniform. On the other hand, in Sample 2, the oxide semiconductor layer 508 formed over the second tungsten layer 510 uniformly covered the second tungsten layer 510 even near the upper end portion of the second tungsten layer 510.

### Example 2

In this example, a top-gate bottom-contact transistor including an oxide semiconductor is described.

In this example, electric characteristics and deterioration of transistors in Sample 3 and Sample 4 were evaluated.

A manufacturing process of Sample 3 and Sample 4 is described below. Note that the manufacturing process is employed for both Sample 3 and Sample 4 unless stated otherwise.

A difference between Sample 3 and Sample 4 is whether plasma treatment (reverse sputtering treatment) is performed on a source electrode and a drain electrode or not. In Sample 3, the reverse sputtering treatment was not performed on the source electrode and the drain electrode, and in Sample 4, the reverse sputtering treatment was performed on the source electrode and the drain electrode.

First, a 100-nm-thick silicon nitride oxide layer was formed over a glass substrate by a plasma CVD method.

Next, a 250-nm-thick silicon oxide layer was formed by a sputtering method. Note that the deposition conditions of the silicon oxide layer are as follows.

Target: quartz target

Deposition gas: Ar (25 sccm), O₂ (25 sccm)

Electric power: 1.5 kW (13.56 MHz)

Pressure: 0.4 Pa

T-S distance: 60 mm

Substrate temperature in deposition: 100° C.

Then, a 100-nm-thick tungsten layer was formed over the silicon oxide layer by a sputtering method. After that, a resist mask was formed through a photolithography process, the tungsten layer was processed by a dry etching method so that a source electrode and a drain electrode are formed, and then the resist mask was removed. At this time, the resist mask was reduced in size by the etching so that the end portions of the source electrode and the drain electrode had a taper angle.

Next, only Sample 4 was subjected to surface treatment by a reverse sputtering method. The conditions of the reverse sputtering are as follows.

Gas: Ar (50 sccm)

Electric power: 0.2 kW (13.56 MHz)

Pressure: 0.6 Pa

Temperature: room temperature

Time: 3 minutes

After the reverse sputtering, a 25-nm-thick oxide semiconductor layer was formed by a sputtering method without breaking a vacuum.

The deposition conditions of the oxide semiconductor layer are as follows.

Target: In—Ga—Zn—O (In₂O₃:Ga₂O₃:ZnO=1:1:2 [molar ratio]) target

Deposition gas: Ar (30 sccm), O₂ (15 sccm)

Electric power: 0.5 kW (DC)

Pressure: 0.4 Pa

T-S distance: 60 mm

Substrate temperature in deposition: 200° C.

Next, the oxide semiconductor layer was processed into an island shaped oxide semiconductor layer by wet etching using a resist mask formed through a photolithography process.

Then, a 30-nm-thick silicon oxynitride layer was formed as a gate insulating layer covering the oxide semiconductor layer, the source electrode, and the drain electrode by a plasma CVD method.

Next, a 30-nm-thick tantalum nitride layer and a 370-nm-thick tungsten layer were formed by a sputtering method. After that, the tantalum nitride layer and the tungsten layer were processed to have a shape of a gate electrode by a dry etching method using a resist mask formed over the tantalum nitride layer and the tungsten layer through a photolithography process.

Then, a 300-nm-thick silicon oxide layer was formed by a sputtering method. The silicon oxide layer functions as an interlayer insulating layer. The interlayer insulating layer and the gate insulating layer were processed using a resist mask formed through a photolithography process, so that a contact hole that reaches the gate electrode, the source electrode, and the drain electrode was formed.

Next, a first titanium layer, an aluminum layer, and a second titanium layer were formed by a sputtering method to have a thickness of 50 nm, 100 nm, and 5 nm, respectively. After that, the first titanium layer, the aluminum layer, and the second titanium layer were processed to have a shape of a wiring by a dry etching method using a resist mask formed through a photolithography process.

Next, heat treatment was performed on each Sample in a nitrogen atmosphere at 250° C. for an hour.

Through the above steps, the transistors for Sample 3 and Sample 4 were manufactured.

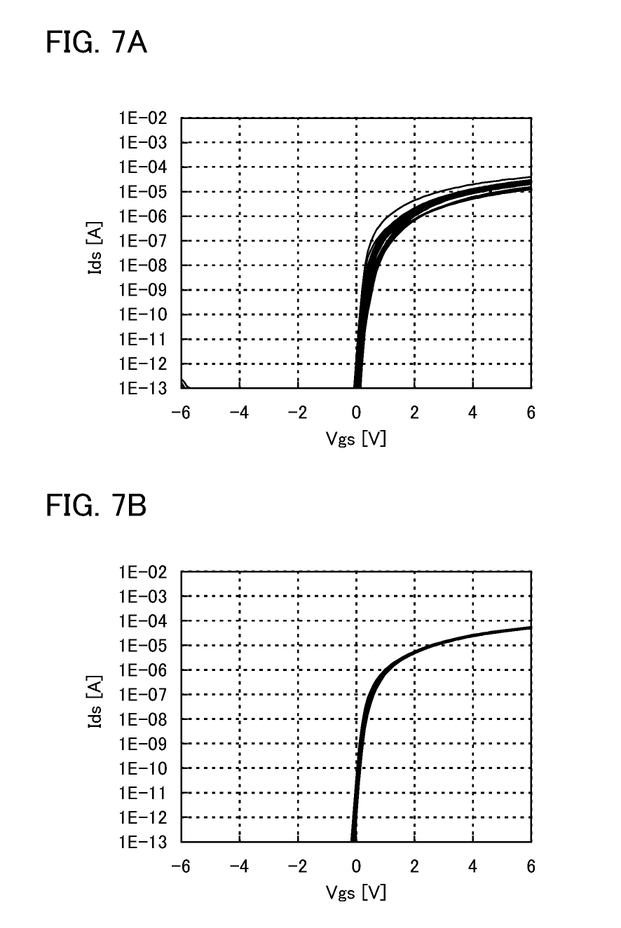

FIGS. 7A and 7B show drain current (Ids)-gate voltage (Vgs) measurement results in the transistor of each Sample of this example. The measurement was performed at 25 points on a substrate surface. The measurement results are shown in a state where they are superimposed. The channel length L was 3 μm and the channel width W was 20 μm. The substrate temperature was 25° C. Note that the voltage Vds between the source electrode and the drain electrode of the transistor was set to 3 V. FIG. 7A shows Ids-Vgs measurement results of the transistor of Sample 3, and FIG. 7B shows Ids-Vgs measurement results of the transistor of Sample 4.

According to the measurement results, a variation in threshold voltage and a decrease and variation in on-state current of the transistor of Sample 4 were small as compared with those of the transistor of Sample 3.

Next, the BT test in this example is described. The transistor on which the BT test is performed has a channel length L of 3 μm and a channel width W of 50 μm. In this example, first, the substrate temperature was set to 25° C. and the voltage Vds between the source electrode and the drain electrode was set to 3 V, and then the Ids-Vgs measurement of the transistor was performed.

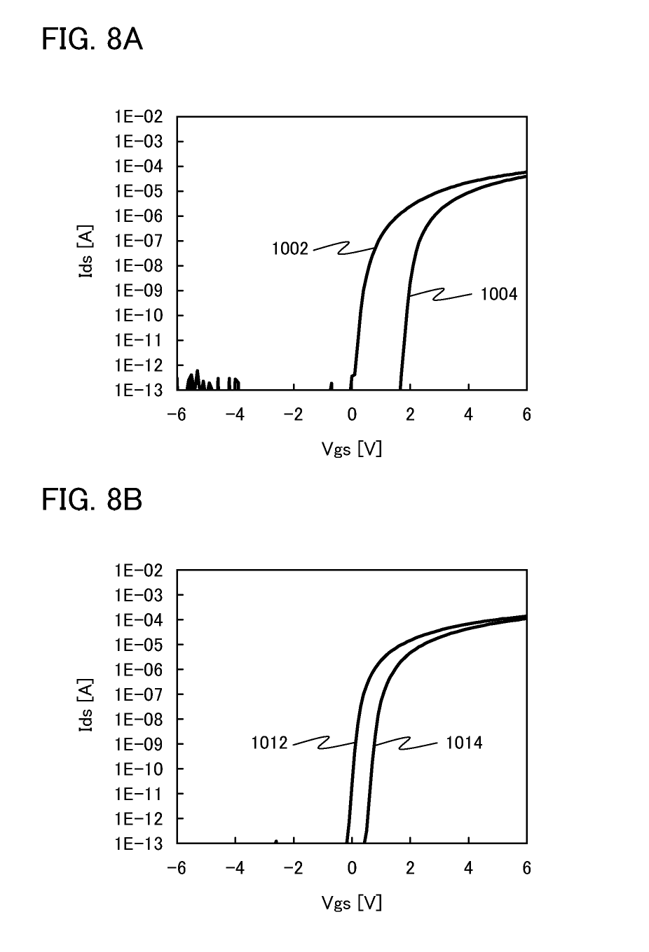

Next, the substrate stage temperature was set to 150° C., and the source electrode and the drain electrode of the transistor were set to 0 V and 0.1 V, respectively. Then, a negative voltage was applied to the gate electrode so that electric-field intensity applied to the gate insulating layer was 2 MV/cm, and the gate electrode was kept for an hour. Next, the voltage of the gate electrode was set to 0 V. After that, the substrate temperature was set to 25° C. and the voltage Vds between the source electrode and the drain electrode was set to 3 V, and the Ids-Vgs measurement of the transistor was performed. FIGS. 8A and 8B show the Ids-Vgs measurement results before and after the BT test of the transistors of Sample 3 and Sample 4, respectively.

In FIG. 8A, a solid line 1002 indicates the Ids-Vgs measurement result of the transistor of Sample 3 obtained before the BT test, and a solid line 1004 indicates the Ids-Vgs measurement result of the transistor of Sample 3 obtained after the BT test. The threshold voltage obtained after the BT test shifted by 1.16 V in the positive direction as compared with the threshold voltage obtained before the BT test.

In FIG. 8B, a solid line 1012 indicates the Ids-Vgs measurement result of the transistor of Sample 4 obtained before the BT test, and a solid line 1014 indicates the Ids-Vgs measurement result of the transistor of Sample 4 obtained after the BT test. The threshold voltage obtained after the BT test shifted by 0.71 V in the positive direction as compared with the threshold voltage obtained before the BT test.

In a similar manner, the Ids-Vgs measurement of another transistor for each Sample was performed under the following conditions: the substrate temperature was set to 25° C.; and the voltage Vds between the source electrode and the drain electrode was set to 3 V. The channel length L of the transistor is 3 μm, and the channel width W thereof is 50 μm.

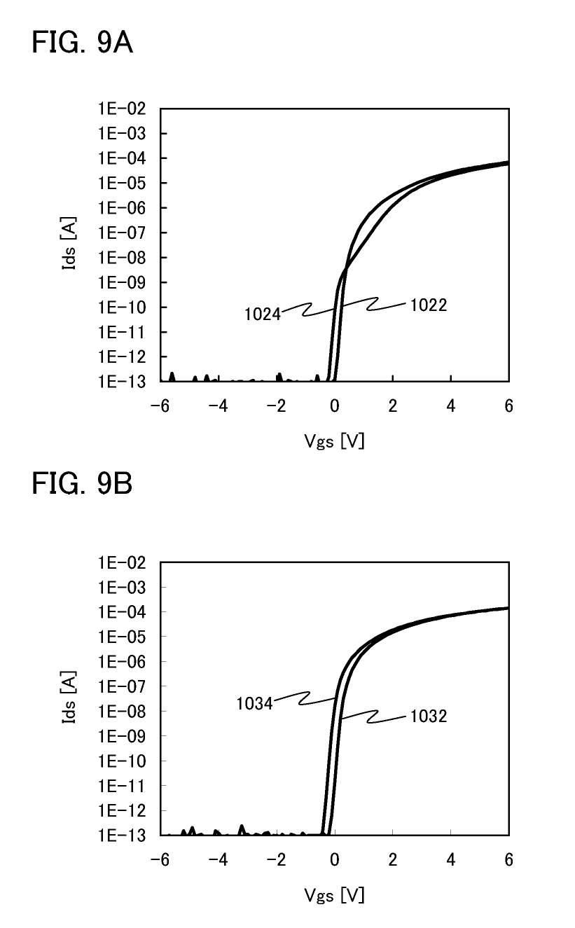

Next, the substrate stage temperature was set to 150° C., and the source electrode and the drain electrode of the transistor were set to 0 V and 0.1 V, respectively. Then, a positive voltage was applied to the gate electrode so that electric-field intensity applied to the gate insulating layer was 2 MV/cm, and the positive voltage was continued to be applied for an hour. Next, the voltage of the gate electrode was set to 0 V. After that, the substrate temperature was set to 25° C. and the voltage Vds between the source electrode and the drain electrode was set to 3 V, and the Ids-Vgs measurement of the transistor was performed. FIGS. 9A and 9B show the Ids-Vgs measurement results before and after the BT test of the transistors of Sample 3 and Sample 4, respectively.

In FIG. 9A, a solid line 1022 indicates the Ids-Vgs measurement result of the transistor of Sample 3 obtained before the BT test, and a solid line 1024 indicates the Ids-Vgs measurement result of the transistor of Sample 3 obtained after the BT test. The Ids-Vgs curve obtained after the BT test was warped and an on-state current obtained after the BT test was decreased as compared with those obtained before the BT test.

In FIG. 9B, a solid line 1032 indicates the Ids-Vgs measurement result of the transistor of Sample 4 obtained before the BT test, and a solid line 1034 indicates the Ids-Vgs measurement result of the transistor of Sample 4 obtained after the BT test. The threshold voltage obtained after the BT test shifted by 0.22 V in the negative direction as compared with the threshold voltage obtained before the BT test.

Next, the photodegradation test in this example is described. The transistor on which the photodegradation test is performed has a channel length L of 3 μm and a channel width W of 50 μm. The substrate temperature was set to 25° C. and the voltage Vds between the source electrode and the drain electrode was set to 3 V. In this example, first, the Ids-Vgs measurement of the transistor was performed in a dark state, and then the Ids-Vgs measurement of the transistor was performed in a light state.

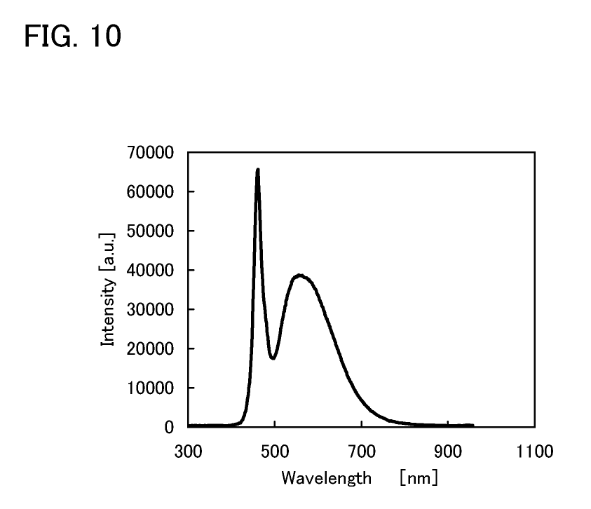

FIG. 10 shows an emission spectrum of light used in this example. Note that the light state refers to a state in which light irradiation with the light having the emission spectrum is performed at illuminance of 36 klx.

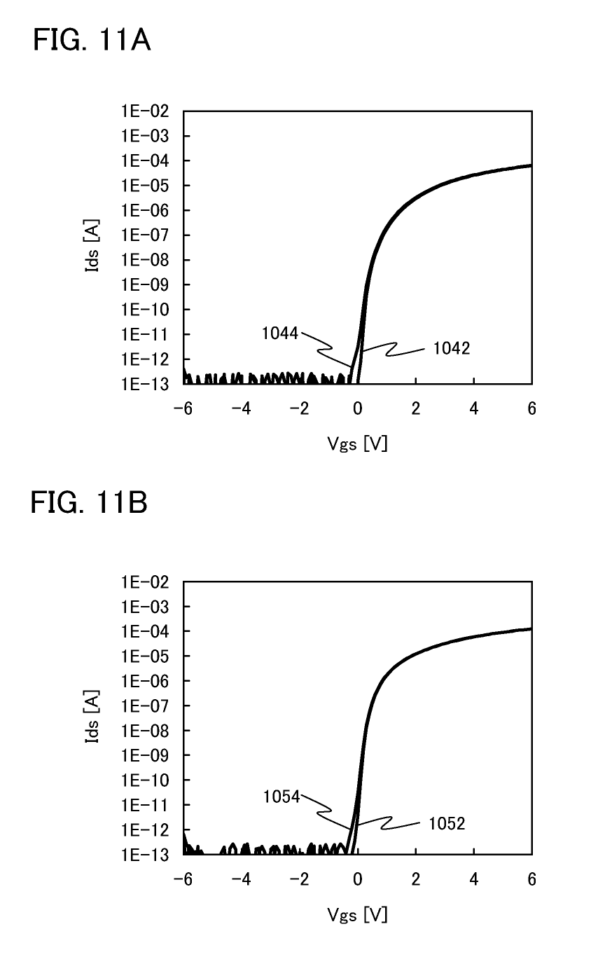

In FIG. 11A, a solid line 1042 indicates the Ids-Vgs measurement result of the transistor of Sample 3 in the dark state, and a solid line 1044 indicates the Ids-Vgs measurement result of the transistor of Sample 3 in the light state. The threshold voltage obtained after the BT test shifted by 0.05 V in the negative direction as compared with the threshold voltage obtained before the BT test.

In FIG. 11B, a solid line 1052 indicates the Ids-Vgs measurement result of the transistor of Sample 4 in the dark state, and a solid line 1054 indicates the Ids-Vgs measurement result of the transistor of Sample 4 in the light state. The threshold voltage obtained after the BT test shifted by 0.01 V in the negative direction as compared with the threshold voltage obtained before the BT test.

As described above, it is found that the transistor of Sample 4 in this example has small variation in threshold voltage of the substrate surface and small degree of deterioration in electric characteristics between before and after the BT test and at the time of light irradiation.

This application is based on Japanese Patent Application serial no. 2010-177037 filed with Japan Patent Office on Aug. 6, 2010, the entire contents of which are hereby incorporated by reference.

What is claimed is:

1. A semiconductor device comprising:
an insulating layer over a substrate;
an oxide semiconductor layer over the substrate;
a source electrode and a drain electrode whose end portion has a taper angle and whose upper end portion has a curved surface, the source electrode and the drain electrode being electrically connected to the oxide semiconductor layer;
a gate insulating layer being in contact with a part of the oxide semiconductor layer and covering the oxide semiconductor layer, the source electrode, and the drain electrode; and
a gate electrode overlapping with the oxide semiconductor layer and being over the gate insulating layer.

2. The semiconductor device according to claim 1, wherein the source electrode and the drain electrode are formed between the gate insulating layer and the oxide semiconductor layer.

3. The semiconductor device according to claim 1, wherein the source electrode and the drain electrode are formed between the substrate and the oxide semiconductor layer.

4. The semiconductor device according to claim 1, wherein the oxide semiconductor layer is formed over and in contact with the insulating layer.

5. The semiconductor device according to claim 1, wherein the source electrode and the drain electrode are formed over and in contact with the insulating layer.

6. The semiconductor device according to claim 1, wherein the amount of oxygen released from the insulating layer is greater than or equal to 1.0×10¹⁸ atoms/cm³.

7. The semiconductor device according to claim 1, wherein the insulating layer comprises silicon oxide in which the number of oxygen atoms per unit volume is more than twice the number of silicon atoms per unit volume.

8. The semiconductor device according to claim 1, wherein the taper angle is greater than or equal to 20° and less than 90°.

9. The semiconductor device according to claim 1, wherein a curvature radius of the upper end portion is greater than or equal to 1/100 and less than or equal to ½ of a thickness of the source electrode and the drain electrode.

10. The semiconductor device according to claim 1, wherein the oxide semiconductor layer comprises at least one of In, Ga, and Zn.

11. The semiconductor device according to claim 1, wherein the gate electrode overlaps with the end portion and the upper end portion.

12. A semiconductor device comprising:
an insulating layer over a substrate;
an oxide semiconductor layer over the substrate;
a source electrode and a drain electrode whose end portion has a taper angle and whose upper end portion has a curved surface, the source electrode and the drain electrode being electrically connected to the oxide semiconductor layer;
a gate insulating layer being in contact with a part of the oxide semiconductor layer and covering the oxide semiconductor layer, the source electrode, and the drain electrode; and
a gate electrode overlapping with the oxide semiconductor layer and being over the gate insulating layer,
wherein an average surface roughness Ra of the source electrode is less than or equal to 0.5 nm.

13. The semiconductor device according to claim 12, wherein the source electrode and the drain electrode are formed between the gate insulating layer and the oxide semiconductor layer.

14. The semiconductor device according to claim 12, wherein the source electrode and the drain electrode are formed between the substrate and the oxide semiconductor layer.

15. The semiconductor device according to claim 12, wherein the oxide semiconductor layer is formed over and in contact with the insulating layer.

16. The semiconductor device according to claim 12, wherein the source electrode and the drain electrode are formed over and in contact with the insulating layer.

17. The semiconductor device according to claim 12, wherein the amount of oxygen released from the insulating layer is greater than or equal to 1.0×10¹⁸ atoms/cm³.

18. The semiconductor device according to claim 12, wherein the insulating layer comprises silicon oxide in which the number of oxygen atoms per unit volume is more than twice the number of silicon atoms per unit volume.

19. The semiconductor device according to claim 12, wherein the taper angle is greater than or equal to 20° and less than 90°.

20. The semiconductor device according to claim 12, wherein a curvature radius of the upper end portion is greater than or equal to 1/100 and less than or equal to ½ of a thickness of the source electrode and the drain electrode.

21. The semiconductor device according to claim 12, wherein the oxide semiconductor layer comprises at least one of In, Ga, and Zn.

22. The semiconductor device according to claim 12, wherein the gate electrode overlaps with the end portion and the upper end portion.

23. A semiconductor device comprising:
an insulating layer over a substrate;
an oxide semiconductor layer over the substrate;
a source electrode and a drain electrode whose end portion has a taper angle and whose upper end portion has a curved surface, the source electrode and the drain electrode being electrically connected to the oxide semiconductor layer;
a gate insulating layer being in contact with a part of the oxide semiconductor layer and covering the oxide semiconductor layer, the source electrode, and the drain electrode; and
a gate electrode overlapping with the oxide semiconductor layer and being over the gate insulating layer,
wherein an average surface roughness Ra of the oxide semiconductor layer is less than or equal to 0.5 nm.

24. The semiconductor device according to claim 23, wherein the source electrode and the drain electrode are formed between the gate insulating layer and the oxide semiconductor layer.

25. The semiconductor device according to claim 23, wherein the source electrode and the drain electrode are formed between the substrate and the oxide semiconductor layer.

26. The semiconductor device according to claim 23, wherein the oxide semiconductor layer is formed over and in contact with the insulating layer.

27. The semiconductor device according to claim 23, wherein the source electrode and the drain electrode are formed over and in contact with the insulating layer.

28. The semiconductor device according to claim 23, wherein the amount of oxygen released from the insulating layer is greater than or equal to 1.0×10¹⁸ atoms/cm³.

29. The semiconductor device according to claim 23, wherein the insulating layer comprises silicon oxide in which the number of oxygen atoms per unit volume is more than twice the number of silicon atoms per unit volume.

30. The semiconductor device according to claim 23, wherein the taper angle is greater than or equal to 20° and less than 90°.

31. The semiconductor device according to claim 23, wherein a curvature radius of the upper end portion is greater than or equal to 1/100 and less than or equal to ½ of a thickness of the source electrode and the drain electrode.

32. The semiconductor device according to claim 23, wherein the oxide semiconductor layer comprises at least one of In, Ga, and Zn.

33. The semiconductor device according to claim 23, wherein the gate electrode overlaps with the end portion and the upper end portion.
